(19) United States
(12) Patent Application Publication
(10) Pub. No.: US 2014/0096816 A1
(43) Pub. Date: Apr. 10, 2014

(54) HETEROJUNCTION MICROWIRE ARRAY SEMICONDUCTOR DEVICES

(71) Applicants: Harry A. Atwater, South Pasadena, CA (US); Nathan S. Lewis, La Canada, CA (US); Andrey D. Poletayev, El Cerrito, CA (US); Morgan C. Putnam, Pasadena, CA (US); Michael D. Kelzenberg, Pasadena, CA (US)

(72) Inventors: Harry A. Atwater, South Pasadena, CA (US); Nathan S. Lewis, La Canada, CA (US); Andrey D. Poletayev, El Cerrito, CA (US); Morgan C. Putnam, Pasadena, CA (US); Michael D. Kelzenberg, Pasadena, CA (US)

(21) Appl. No.: 13/994,702

(22) PCT Filed: Dec. 22, 2011
(86) PCT No.: PCT/US11/67055

§ 371 Date: Dec. 20, 2013

Related U.S. Application Data
(60) Provisional application No. 61/426,397, filed on Dec. 22, 2010.
(60) Provisional application No. 61/578,852, filed on Dec. 21, 2011.

(51) Int. Cl. H01L 31/0352; H01L 31/075; H01L 31/072; H01L 31/042; H01L 31/18

(52) U.S. Cl. CPC H01L 31/035281; H01L 31/042; H01L 31/1876; H01L 31/072; H01L 31/075
USPC 136/255; 438/73

(57) ABSTRACT

A heterojunction semiconductor device including an array of microstructures, each microstructure including a microwire of a first semiconductor material and a coating of a second semiconductor material forming a heterojunction with the microwire; a first electrical contact and a second electrical contact, one of which is connected to the microwire and the other of which is connected to the coating, is described. Also described are considerations for configuring the array of microstructures, and methods of forming the array of microstructures.

### CROSS-REFERENCE TO RELATED APPLICATION(S)

This non-provisional application claims priority to and the benefit of U.S. Provisional Application Ser. No. 61/426,397, filed on Dec. 22, 2010, entitled SILICON HETEROJUNCTION MICROWIRE ARRAY PHOTOVOLTAICS, and U.S. Provisional Application Ser. No. 61/578,852, filed on Dec. 21, 2011, entitled HETEROJUNCTION MICROWIRE ARRAY SEMICONDUCTOR DEVICES, the entire contents of each of which are incorporated herein by reference.

### STATEMENT REGARDING FEDERALLY SPONSORED RESEARCH OR DEVELOPMENT

This invention may have been made with government support awarded by the U.S. Department of Energy. The government may have certain rights in the invention.

### FIELD

The following description generally relates to heterojunction arrays of microstructures and methods of making the same. More specifically, the following description generally relates to arrays of microstructures for heterojunction semiconductor devices and methods of making the same.

### BACKGROUND

Semiconductor devices can be used in a variety applications, such as in photovoltaic devices (e.g., solar cells). The sun is a source of clean energy, but the cost of energy extraction for solar cells remains high relative to fossil fuels. Therefore, the fabrication of cheap and efficient photovoltaic devices is an important engineering challenge. The factors generally limiting the efficiency of photovoltaic devices (beyond thermodynamic and quantum mechanical considerations) are series and shunt resistances, incomplete optical absorption, and minority charge carrier recombination, particularly at the interfaces. To address the later issue, planar silicon-based solar cells have been prepared using an amorphous Si (a-Si) heterojunction, such as the heterojunction with thin intrinsic layer (HIT) structure (“HIT” is a trademark of SANYO Electric Co., Ltd.).

In the p-i-n structure of planar HIT cells, the thin intrinsic layer is sandwiched between the highly-doped p⁺-type hydrogenated amorphous silicon (a-Si:H, hereafter a-Si) emitter and n-type crystalline silicon (c-Si) absorber, which is traditionally a wafer. The intrinsic region is easily depleted of thermally excited charge carriers, and its inclusion increases the effective depletion width for the junction. Consequently, the built-in electric field becomes spread over a larger distance and weakens, decreasing charge carrier recombination and allowing for larger open circuit voltages (V_{oc}) and efficiencies. Previous planar HIT cells have achieved solar energy conversion efficiencies approaching 25%. Planar n⁺-i-p heterojunction cells also have been shown to have comparable efficiencies (e.g., 19.3%), so the particular dopant type is not necessarily a deciding factor in the utility of the heterojunction structure.

However, manufacturing the high-purity crystalline silicon absorber necessary for charge carrier collection remains a significant component of the cost of planar heterojunction photovoltaic devices and other analogous semiconductor devices. There remains a need to produce semiconductor devices, such as photovoltaic devices, that are more efficient and cheaper to produce than existing devices.

### SUMMARY

Embodiments of the present invention are directed to an array of microstructures, which may be used in a heterojunction semiconductor device, such as a photovoltaic device. For example, in certain embodiments, a heterojunction semiconductor device includes an array of microstructures, each microstructure including a microwire of a first semiconductor material and a coating of a second semiconductor material forming a heterojunction with the microwire, a first electrical contact and a second electrical contact, one of which is connected to the microwire and the other of which is connected to the coating. By using an array of microstructures, the quantity and purity requirements for the first semiconductor (e.g., crystalline silicon) are reduced, thereby reducing the cost of device fabrication. Additionally, the heterojunction decreases charge carrier recombination and allows for greater open circuit voltages, thereby increasing device efficiency. At the same time, the presence of the heterojunction introduces new challenges related to photogeneration and parasitic absorption (e.g., light absorption in the coating) that requires consideration of device parameters that are not similarly important for microstructures that do not include a heterojunction.

In certain embodiments, the first semiconductor material and the second semiconductor material have different bandgaps. For example, the first semiconductor material may include a material selected from the group consisting of Si, Ge, SiGe, GaAs, CdTe, CdSe, GaN, GaP, GaAsP, GaInP, AlInP, InGaN, and combinations thereof. As another example, the second semiconductor material may include a material selected from the group consisting of Si, Ge, SiGe, GaAs, CdTe, CdSe, GaN, GaP, GaAsP, GaInP, AlInP, InGaN, and combinations thereof.

In certain embodiments, the microwire is configured to be substantially parallel to the direction of propagation of incident light. For example, the microwire may be configured to absorb light that propagates along the length of the microwire. Additionally, the microwire may be configured to have photogenerated minority charge carriers diffuse in a direction that is orthogonal to the direction of propagation of incident light.

In certain embodiments, the heterojunction is a p-i-n or n-i-p heterojunction. In certain embodiments, the coating concentrically surrounds a portion of the microwire. For example, the coating may concentrically surround less than half of the elongated portion of the microwire. As another example, the coating may concentrically surround more than half of the elongated portion of the microwire. In certain embodiments, the coating on each microwire is discontinuous with the coating on adjacent microwires. In certain embodiments, the first electrical contact or the second electrical contact comprises a semiconductor that forms a non-rectifying heterojunction to the microwire.

In certain embodiments, the thickness of the coating narrows at it extends along the length of the microwire. In certain embodiments, the second electrical contact is reflective. The microstructures may penetrate into a portion of the second electrical contact.

In certain embodiments, the microwire has a diameter in a range of about 1 μm to about 10 μm. For example, the microwire may have a diameter in a range of about 1.5 μm to about 4 μm. As another example, the microwire has a length of greater than 75 μm. As yet another example, the microwire may have a length in a range of about 25 μm to about 75 μm. In still another example, the microwire may have a length of greater than 50 μm. In certain embodiments, at least a portion the coating has a thickness in a range of about 5 nm to about 10 nm. In certain embodiments, one end of the microstructure has a pyramidal or a conical shape.

In certain embodiments, the second semiconductor material comprises a dopant in a range of about 1 to about 10 weight percent based on the total weight of the second semiconductor material. For example, the second semiconductor material may include a dopant formed from a phosphine or diborane precursor.

The microstructures may be partially or fully embedded in an infill material. The infill material may include a polymer or glass. For example, the polymer may include polydimethylsiloxane. In certain embodiments, the infill material includes light scattering particles. In certain embodiments, the microstructure further comprises an anti-reflective coating.

In certain embodiments, a method of preparing an array of microstructures for heterojunction a semiconductor device includes: growing an array of microwires on a substrate, the microwires comprising a first semiconductor material; and depositing a second semiconductor material on a portion of the microwires to form a heterojunction. For example, growing the array of microwires may include vapor-liquid-solid (VLS) chemical vapor deposition (CVD). As an example, the substrate may include a VLS catalyst. In certain embodiments, the VLS catalyst is a copper or nickel catalyst. The VLS deposition may be carried out at a pressure in a range of about 500 to about 800 torr. The VLS deposition may be carried out with a gas flow comprising hydrogen and a chlorosilane. As an example, the VLS deposition may be carried out with a ratio of hydrogen to chlorosilane in a range of about 200:1 to about 25:1. The VLS deposition may be carried out at a temperature in a range of about 850 to about 1100° C.

In certain embodiments, a gas is introduced during the growing of the array of microstructures and the gas composition is controlled to produce an axial or radial doping profile. In certain embodiments, the array of microwires is removed from the substrate on which it was grown.

In certain embodiments, depositing the second semiconductor material includes a method selected from the group consisting of plasma-enhanced chemical vapor deposition (PECVD), hot wire chemical vapor deposition (HWCVD), metalorganic chemical vapor deposition (MOCVD), atmospheric pressure chemical vapor deposition (APCVD), low pressure chemical vapor deposition (LPCVD), atomic layer deposition (ALD), evaporation, sputtering, and combinations thereof. For example, the PECVD or HWCVD may be carried out at a pressure in a range of about 400 to about 500 millitorr. The PECVD or HWCVD may be carried out at a substrate temperature in a range of about 220 to about 250° C.

In certain embodiments, the PECVD or HWCVD is carried out in the presence of a hydrogen gas mixture including a chlorosilane. Additionally, the hydrogen gas mixture may further include phosphine or diborane in an amount in a range of about 1 to about 10 weight percent based on the total weight of the hydrogen gas mixture.

In certain embodiments, preparing the array of microstructures for the heterojunction semiconductor device further includes removing the VLS catalyst from the substrate before depositing the second semiconductor material.

In certain embodiments, the method further includes oxidizing the microwires before depositing the second semiconductor material.

In certain embodiments, the method further includes covering a portion of each microwire to leave an exposed portion, before depositing the second semiconductor material on the exposed portion of the microwire to form the heterojunction.

In certain embodiments, the first semiconductor material is different from the second semiconductor material. For example, the first semiconductor material may include a material selected from the group consisting of crystalline silicon, Ge, GaAs, CdTe, CdSe, GaN, and GaP. As another example, the second semiconductor material may include amorphous silicon or gallium phosphide (GaP). In certain embodiments, the heterojunction is a p-i-n heterojunction. In certain embodiments, growing the array of microwires on the substrate forms microwires that are substantially perpendicular to the substrate. In certain embodiments, the second semiconductor material is deposited over the array of microstructures and selectively removed from a portion of the array of microstructures using lift-off, ablation or an etch.

### BRIEF DESCRIPTION OF THE DRAWINGS

The accompanying drawings, together with the specification, illustrate exemplary embodiments of the invention, and, together with the description, serve to explain the principles of the invention.

FIG. 1 is a perspective view of an array of microstructures according to an exemplary embodiment.

FIGS. 2A through 2D are cross-sectional views of microstructures according to exemplary embodiments.

FIG. 3 is an exploded, perspective, cross-sectional view of a microstructure according to an exemplary embodiment.

FIG. 4 is a perspective view of an array of microstructures according to an exemplary embodiment.

FIG. 5 is an exploded, perspective, cross-sectional view of a microstructure according to an exemplary embodiment.

FIG. 6 is a perspective view of an array of microstructures according to an exemplary embodiment.

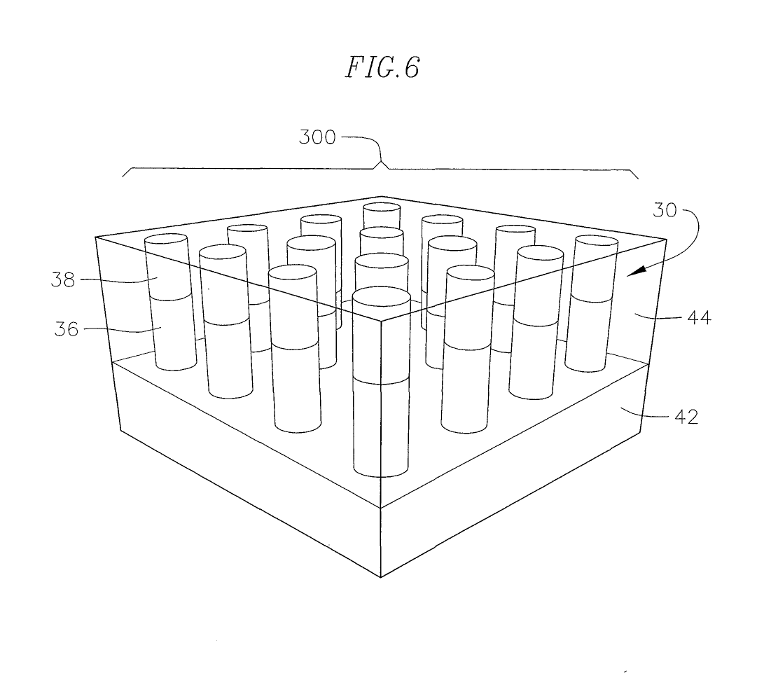

FIG. 7 is an exploded, perspective, cross-sectional view of a microstructure according to an exemplary embodiment.

FIG. 8 is a perspective view of an array of microstructures according to an exemplary embodiment.

FIG. 9 is an exploded, perspective, cross-sectional view of a microstructure according to an exemplary embodiment.

FIG. 10 is a perspective view of an array of microstructures according to an exemplary embodiment.

FIGS. 11A through 11D are cross-sectional views of microstructures according to exemplary embodiments.

FIG. 12 is a perspective view of an array of microstructures including light scattering particles according to an exemplary embodiment.

FIG. 13 is an optical micrograph of an exemplary microwire array.

FIG. 14 is an optical micrograph of an exemplary microwire array.

### DETAILED DESCRIPTION

In the following detailed description, only certain exemplary embodiments of the invention are shown and described, by way of illustration. As those skilled in the art would recognize, the invention may be embodied in many different forms and should not be construed as being limited to the embodiments set forth herein. Like reference numerals designate like elements throughout the specification.

Additionally, in the following detailed description, various features are described as being “on” one or more additional feature(s). This language simply denotes the relative positions of the features. Thus, in some embodiments, two features are literally right next to each other, while in other embodiments, the same two features are separated by one or more additional feature(s). In each case, one of the two features is considered to be “on” the other feature. Also, “on” can mean “below.” For example, a feature that is “on” another feature can also be considered “below” the other feature, depending upon the point of view. Further, as used herein, the term “microwire” is used in a general sense to encompass structures that would have surfaces falling within a traditional definition of a cylinder (i.e., a surface formed by a closed curve that is moved in a direction not within its plane). As used herein, the term “coating” refers to a layer that may be continuous or discontinuous.

Embodiments of the invention will now be described with reference to the accompanying drawings, in which exemplary embodiments of the invention are shown. The drawings are illustrative in nature and are not to be construed as limiting the invention. In the drawings, the thicknesses of layers and regions may be exaggerated for ease of illustration.

Embodiments of the present invention are directed to an array of microstructures, which may be used in a heterojunction semiconductor device, such as a photovoltaic device. Each microstructure may include a microwire and a coating forming a heterojunction with the microwire. The microwire and coating may include first and second semiconductors, respectively. Each microstructure may also include a first electrical contact and a second electrical contact, one of which is connected to the microwire and the other of which is connected to the coating. By using an array of microstructures, the quantity and purity requirements for the first semiconductor (e.g., crystalline silicon) are reduced, thereby reducing the cost of device fabrication. Additionally, the heterojunction decreases charge carrier recombination and allows for greater open circuit voltages, thereby increasing device efficiency. At the same time, the presence of the heterojunction introduces new challenges related to photogeneration and parasitic absorption (e.g., light absorption in the coating) that requires consideration of device parameters that are not similarly important for microstructures that do not include a heterojunction.

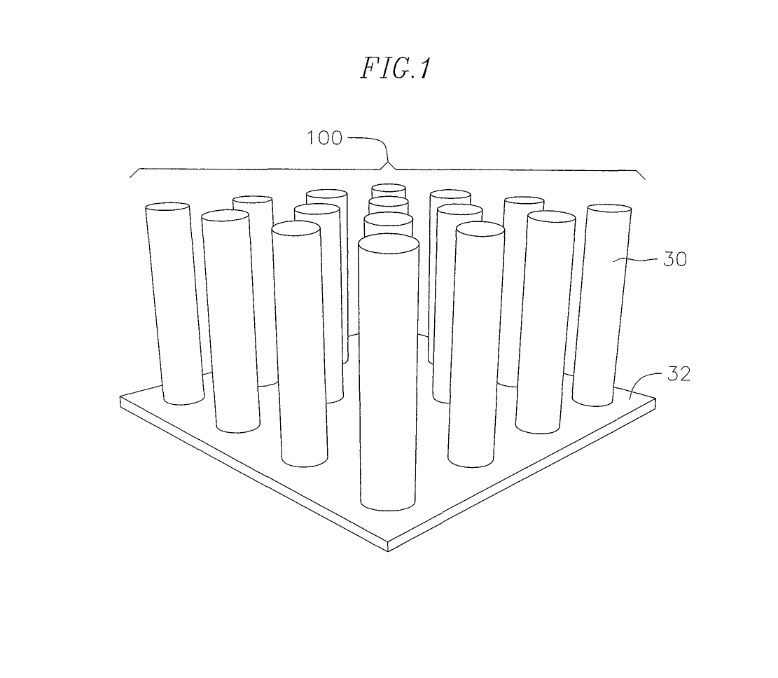

FIG. 1 is a perspective view of an array 100 of microstructures 30 according to an exemplary embodiment of the invention, in which certain features have been omitted for clarity. As can be seen in FIG. 1, the array includes a plurality of microstructures 30 spaced apart from one another. The microstructures 30 may be spaced apart from one another by any suitable distance, such as a distance in a range of about 3 μm to about 10 μm. In certain embodiments, the array is on a support 32, which can be any suitable support, such as the substrate on which the microstructures 30 are grown (i.e., the growth substrate), the substrate from which the microstructures are etched, or a substrate to which the microstructures 30 have been transferred, such as glass, plastic, aluminum foil, stainless steel, mylar, or other rigid or flexible materials. Additional features, some of which are described below, may be further included in the array 100.

The array 100 may be included in heterojunction semiconductor devices such as photovoltaic devices (e.g., solar cells). For example, the array may be included in an HIT cell, Schottky cell, metal-insulator-semiconductor (MIS) cell, photoelectrochemical cell (e.g., for the production of hydrogen or syngas), a Swanson-type PIN cell, or any other suitable semiconductor device. Additionally, the array may be included in multi-junction photovoltaic devices and tandem cells.

In exemplary embodiments of the invention, the microstructures 30 include microwires (described further below), which include a first semiconductor material, such as crystalline silicon (c-Si). Because the microwires are spaced apart from one another, the microwires include significantly less first semiconductor material than would a continuous layer having a thickness equal to the length of the microwires (e.g., the thickness of the layer formed by the microwires). This reduction in the amount of the first semiconductor material can provide a significant reduction in the cost of a device. For example, a substantial contributor to the cost of planar HIT solar cells, and other c-Si containing photovoltaic devices, is the expense of manufacturing the high-purity c-Si necessary for charge carrier collection. A semiconductor device that includes c-Si in the form of microwires uses significantly less c-Si than would an analogous device including a continuous layer of c-Si. Consequently, the device including, for example, c-Si microwires will be significantly less expensive to produce than an analogous device including a continuous layer of c-Si. Additionally, as will become apparent from the following description, the characteristics of the array allow for c-Si microwires to have lower purity than is required for the c-Si of planar heterojunction photovoltaic devices, such as planar HIT solar cells. Consequently, c-Si microwires according to embodiments of the invention can be prepared by processes that are less expensive than those required for preparing the continuous c-Si layer typically used in semiconductor devices such as planar heterojunction photovoltaic devices.

In exemplary embodiments of the invention, the microstructures 30 exhibit photonic light-trapping behavior owing to the photonic scale of the semiconductor microwires and to light-trapping elements that may be included within the array and/or microstructures (discussed further below). For example, certain embodiments of the invention include light-trapping elements such as those described in U.S. patent application Ser. No. 12/957,065, and Kelzenberg, M. D., Boettcher, S. W., Petykiewicz, Turner-Evans, D. B., Putnam, M. C., Warren, E. L., Spurgeon, J. M., Briggs, R. M., Lewis, N. S., and Atwater, H. A. (2010) Nature Materials 2365, the entire contents of each of which are herein incorporated by reference. Because of the photonic light-trapping effects of the microstructures, photovoltaic devices (e.g., solar cells) including such microstructures absorb more light than conventional, randomly or pyramidially textured photovoltaic devices, such as planar HIT solar cells, and can thus achieve greater efficiency than conventional photovoltaic devices, for a given amount of semiconductor material.

The two performance limitations for planar c-Si/a-Si heterojunction solar cells, such as HIT cells, are series resistance and optical losses in the a-Si and top contact. In general, the series resistance can be decreased by increasing the thickness of the a-Si and top contact layer. However, this has the effect of increasing the optical losses, since all light must pass through the a-Si and top contact layers before reaching the active region of the cell. In contrast, the microstructures 30 of the present invention can be optimized to reduce optical losses and series resistance by placing the a-Si on the sides or back of the microwires 34, relative to the direction of illumination.

Additionally, according to embodiments of the invention, the microwires can include semiconductor materials that have higher resistivity than would be suitable for the semiconductor materials used in nanowires. Nanowires exhibit enhanced optical absorption due to their sub-wavelength structure. Nanowire solar cells have high carrier collection efficiency owing to the submicron distance carriers must travel to reach the junction, and can thus better tolerate low-purity, low-diffusion-length semiconductor materials. However, the open-circuit voltage of such solar cells remains sensitive to the minority-carrier lifetime, and thus also the purity of the semiconductor material. Therefore, to improve the efficiency of nanowire solar cells, higher-purity, more resistive semiconductor materials must be used. This presents a problem for nanowire solar cells, because at such low doping levels, the crystalline Si nanowire (i.e., “core”) becomes fully depleted. In numerical simulations of photovoltaic devices carried out by the present inventors, core depletion drastically reduces the short-circuit current because the majority-carrier conduction channel becomes pinched off. In contrast, microwire heterojunction solar cells permit the use of higher-resistivity Si without suffering from core depletion, while still providing the photonic light-trapping benefits as described above.

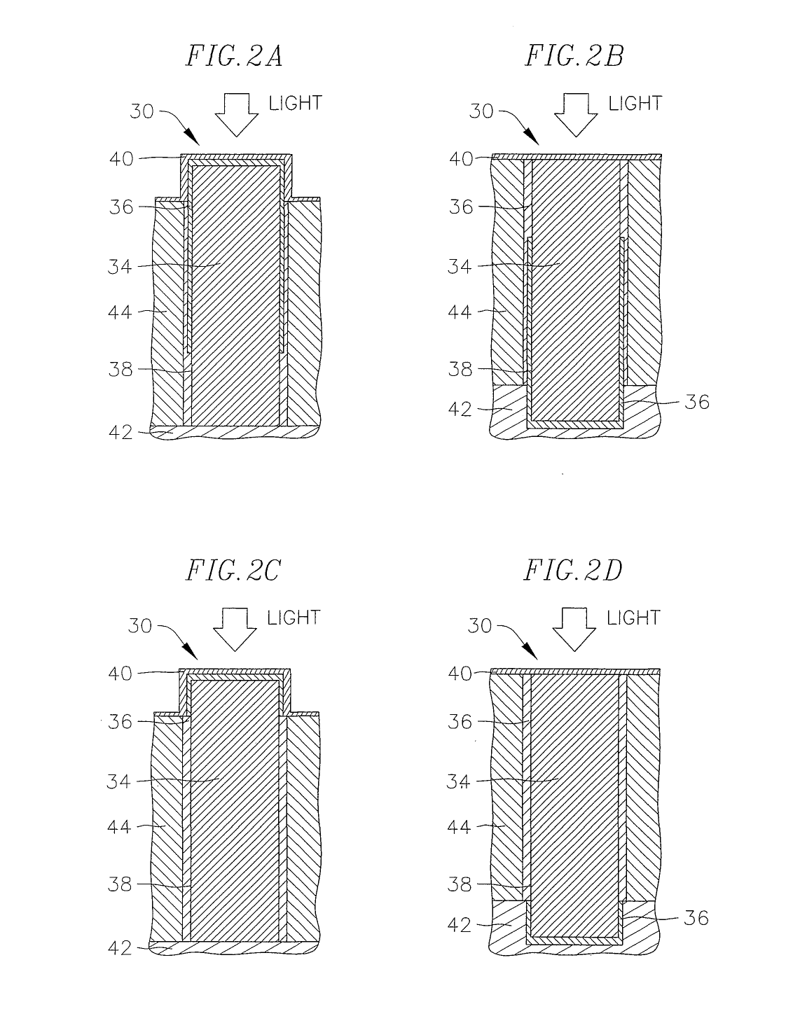

FIGS. 2A through 2D show cross-sectional views of individual microstructures 30 according to exemplary embodiments of the invention. As shown in FIGS. 2A and 2D, an exemplary microstructure 30 includes a microwire 34 (i.e., an “absorber,” “base,” or “core”), a coating 36 (e.g., an emitter), an anti-reflective coating (ARC) 38, a first electrical contact 40 (e.g., a transparent conductive oxide, such as indium tin oxide), a second electrical contact 40 (e.g., back contact or reflecting contact), and an infill material 44 (e.g., a dielectric infill material). The coating 36 may also include an intrinsic region (not shown) at the interface between the microwire 34 and the coating 36.

In certain embodiments the microwire 34 includes a first semiconductor material, such as c-Si, a-Si, Ge, GaAs, CdTe, CdSe, GaN, GaP, or any other suitable semiconductor material. That is, the microwire 34 may include a material selected from the group consisting of Si, Ge, SiGe, GaAs, CdTe, CdSe, GaN, GaP, GaAsP, GaInP, AlInP, InGaN, and combinations thereof. The coating 36 includes a second semiconductor material, such as hydrogenated amorphous silicon (a-Si), c-Si, Ge, SiGe, GaAs, CdTe, CdSe, GaN, GaP, GaAsP, GaInP, AlInP, InGaN, alloys thereof, or any other suitable semiconductor material. That is, the coating may include a material selected from the group consisting of Si, Ge, SiGe, GaAs, CdTe, CdSe, GaN, GaP, GaAsP, GaInP, AlInP, InGaN, and combinations thereof. Additionally, but not necessarily, the second semiconductor material may be further subdivided into two or more regions of different doping, with a region of lower doping (“intrinsic region”) located nearer the interface between the second semiconductor material and the first semiconductor material, and a region of higher doping (“doped region”) located further from the interface.

The anti-reflective coating may include any suitable anti-reflective material, such as SiNₓ, SiOₓ, Al₂O₃, titanium dioxide, a polymer, or any other coating having suitable anti-reflective properties, and the anti-reflective coating may also serve as a surface passivation layer for the first or second semiconductor material. Ideally, but not necessarily, the anti-reflective coating has a refractive index value between that of the infill material 44 and that of the semiconductor material it coats. The first electrical contact 40 may include any suitable transparent conductive coating, such as a transparent conductive oxide, transparent conductive polymer, transparent conductive nanostructure mesh, or any other coating having suitable conductivity and optical transmittance. For example, the first electrical contact 40 may include indium tin oxide (ITO), indium zinc oxide (IZO), aluminum-doped zinc oxide (AZO), Ag nanowires, carbon nanotubes, graphene, or poly(3,4-ethylenedioxythiophene) (PEDOT), but it is not limited thereto. The second electrical contact may include any suitable metal, such as Ag, Au, Cr, Cu, Ga, In, Ni, alloys thereof, stainless steel, or any other material having suitable conductivity, and the second electrical contact 40 may be reflective.

The semiconductor microwire may include a layer or region of increased doping (not shown) at the interface to the second electrical contact (i.e., a back-surface field), as is common for solar cells. Alternatively, the second electrical contact may include one or more thin semiconductor layers (not shown) that form a non-rectifying heterojunction between the metal and the semiconductor microwire (i.e., a minority carrier mirror), as seen in HIT solar cells. The infill material 44 may include any suitable infilling material, such as a polymer or glass, but it is not limited thereto. For example, the infill material 44 may include polydimethylsiloxane (PDMS), other silicones, ethyl vinyl acetate (EVA), polyvinyl butyral (PVB), a spin-on glass, or any other material having suitable in-filling properties. Additionally, the infill material 44 may further include light trapping elements, such as light scattering particles comprising alumina, titanium dioxide, or any other material having suitable light reflective properties. In certain embodiments, the microstructures 30 are partially or fully embedded in the infill material 44. Furthermore, in certain embodiments, the functionality of the infill material 44 and the first electrical contact 40 may be served by a single material or composite structure that provides both the mechanical infill of the structure as well as electrical conductivity.

According to embodiments of the invention, the first semiconductor material is different from the second semiconductor material. While the first and second semiconductor materials may include similar elemental composition, they are different from one another in that the first and second semiconductor materials have different bandgaps. For example, in certain embodiments, the microwire 34 includes c-Si, and the coating 36 includes a second semiconductor material that has a different bandgap from that c-Si, such as a-Si. As such, the second semiconductor material (i.e., coating 36) may form a heterojunction with the microwire 34. The heterojunction may also include the above-described intrinsic region, which may also include a second semiconductor material that has a different bandgap from that of c-Si. Because the intrinsic region is easily depleted of thermally excited charge carriers, its inclusion increases the effective depletion width for the heterojunction. Consequently, the built-in electric field becomes spread over a larger distance, decreasing charge carrier recombination and allowing for larger open circuit voltages (V_{oc}) and efficiencies.

For example, the first semiconductor material may include c-Si, which has a bandgap of about 1.1 eV, while the second semiconductor material may include hydrogenated amorphous silicon (a-Si), which has a bandgap of about 1.7 eV.

As another example, the second semiconductor material may include gallium phosphide (GaP). GaP is lattice-matched with Si, and the bandgap of GaP (about 2.3 eV) is larger than that of a-Si, so V_{oc} should improve when using GaP (see equation 2, shown below, provided other factors are not limiting). Furthermore, the bandgap of GaP may be altered, for example, by doping with nitrogen or zinc oxide, to obtain different bandgaps or band offsets relative to c-Si.

As described above, the microstructure 30 may also include an anti-reflective coating (ARC) 38. In certain embodiments the ARC 38 functions as a passivation layer as well as an anti-reflective coating. For example, the ARC may include SiNₓ, to passivate the coating 36 or the first semiconductor material. That is, the microstructure 30 may include a SiNₓ layer on (e.g., physically contacting) the coating 36 and/or the microwire 34. Including an ARC 38 that passivates the coating 36 should improve the minority charge carrier lifetime, by reducing recombination at the passivated surfaces and/or interfaces, thereby increasing the efficiency of photovoltaic devices or other minority-carrier devices made from microstructures 30.

$$\begin{matrix}{V}_{oc} = \frac{{k}_{B} T}{q} exp ( \frac{{J}_{sc}}{γ {J}_{0}} ) & Equation 1 \\ \frac{{J}_{n}}{{J}_{p}} = \frac{{N}_{D , abs}}{{N}_{A , sm}} \frac{exp ( ( - ( Δ ) {E}_{g} )}{{k}_{B} T} & Equation 2\end{matrix}$$

Because the microstructures 30 include a heterojunction, the light absorption characteristics of the microstructures 30 are different from those for microstructures including a homojunction. These differences in light absorption characteristics are due, in part, to the microwire 34 and coating 36 being formed of different materials (e.g., the first semiconductor material and the second semiconductor material, respectively). In microstructures including a homojunction, the materials of the base and the emitter are the same and, therefore, the light absorption characteristics are not significantly altered by which material (e.g., the base or the emitter) the light passes through first. While the position of the charge-separating homojunction with respect to the direction of illumination affects the transport and collection of charge carriers, it does not affect the optical properties of the microstructure per se.

In contrast, the microwire 34 and coating 36 according to embodiments of the invention have different light absorption characteristics and, consequently, the light absorption characteristics may be significantly altered by which material (e.g., the microwire 34 or the coating 36) the light passes through first. That is, the microstructures 30 according to embodiments of the invention interact with light anisotropically. Accordingly, both optical absorption and carrier collection should be considered when selecting the configuration of the array and the configuration of the microstructures themselves. For example, the heterojunction may be configured to be close to the absorbing areas of the microstructure 30 for optimal charge collection, while the array may be, additionally or alternatively, configured to avoid parasitic absorption in the coating 36. For example, for a-Si/c-Si heterojunctions, the direct bandgap and low minority carrier diffusion lengths in a-Si have the potential to compromise efficient collection of carriers generated in the a-Si (i.e., giving rise to parasitic absorption in the a-Si). A similar phenomenon has been observed for planar (wafer-based) heterojunction solar cells. In this example case, the microstuctures 30 may be configured to guide light into microwires 34, which may include c-Si, rather than into the coating 36, which may include a-Si:H. The above-described considerations are not readily discernible from microstructures that do not include a heterojunction (e.g., microstructures that include a homojunction instead). Furthermore, the non-contiguous nature of the microstructures 30 differs from the case of planar (wafer-based) heterojunction solar cells, which require the a-Si layer to be placed either at the top or bottom surface of the c-Si wafer with respect to illumination. In the case of the present invention, the coating 36 may be selectively placed at the top, bottom and sides of the microwires 34, or portions thereof, with respect to the direction of illumination.

As described further below, the array can be configured such that optical generation occurs primarily in the microwire 34, rather than other portions of the microstructure 30, such as the coating 36. Nonetheless, in instances where collection from the coating 36 is possible, the array and microstructures 30 can be configured to absorb largely in the coating 36. Based on the measured charge carrier lifetimes in fabricated amorphous silicon, for example, photoactivity in a thin a-Si coating 36 on microstructures 30 may be possible. Furthermore, the charge carrier collection efficiency may vary within the coating 36. For example, when the coating material contains a doped region and an intrinsic region (i.e., forming a p-i-n or n-i-p heterojunction), the presence of an electric field within the intrinsic region ensures high charge carrier collection efficiency within the intrinsic region, whereas the higher doping, lack of a significant electric field (i.e., quasi-neutrality), and proximity to the coating surface within the doped region can cause lower carrier collection efficiency within the doped region, depending on the geometry and materials employed. In such cases, the array and microstructures 30 can be configured to absorb largely in the microstructure 30 and the regions of high charge carrier collection efficiency within the coating 36.

As examples, FIGS. 2A through 2D show four configurations of microstructures 30 according to exemplary embodiments of the invention. FIGS. 2A and 2D show a configuration in which the microstructure 30 includes the microwire 34 of the first semiconductor material and the coating 36 (e.g., emitter) of the second semiconductor material forming the heterojunction with the microwire 34; the first electrical contact 40 and the second electrical contact 40, one of which is connected to the microwire 34 and the other of which is connected to the coating 36. In each of FIGS. 2A through 2D, at least a portion of the coating is on the elongated portion of the microwire 34. For example, in FIG. 2A, the coating 36 (e.g., emitter) is on (e.g., concentrically on) more than half of the elongated portion of the microwire 34. As such, the coating 36 at least partially covers the elongated portion of the microwire 34. Additionally, in this embodiment, the coating may also partially or fully cover one end of the microwire 34. This embodiment is referred to as a “radial” configuration (i.e., a radial junction).

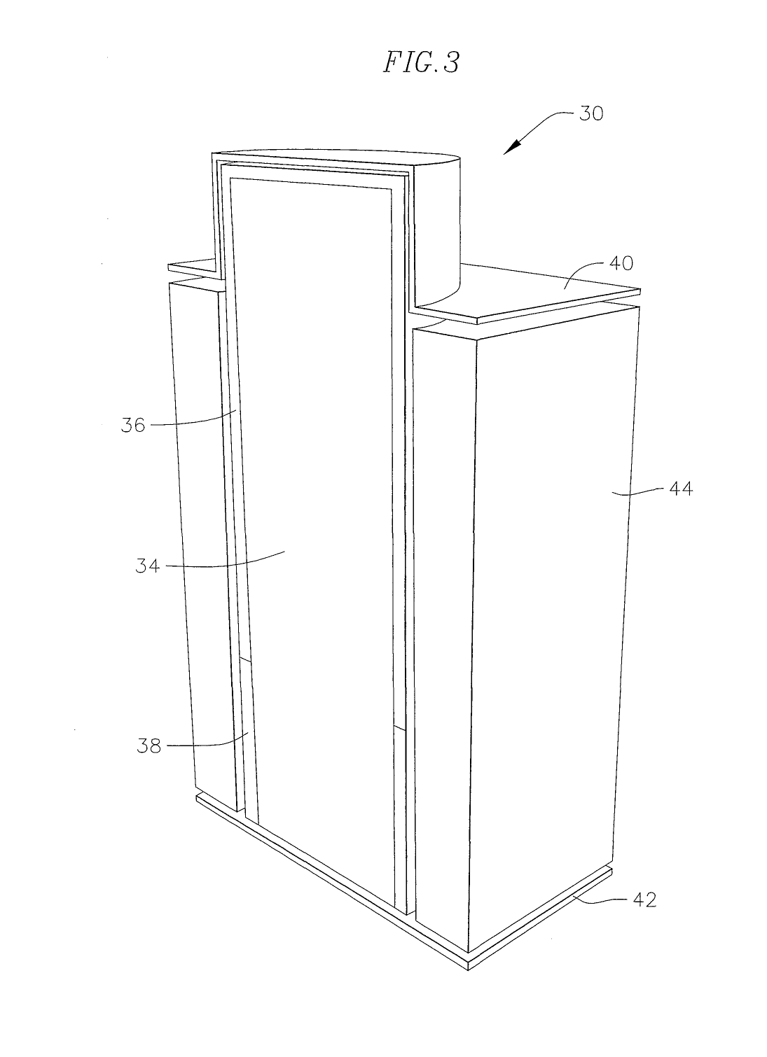

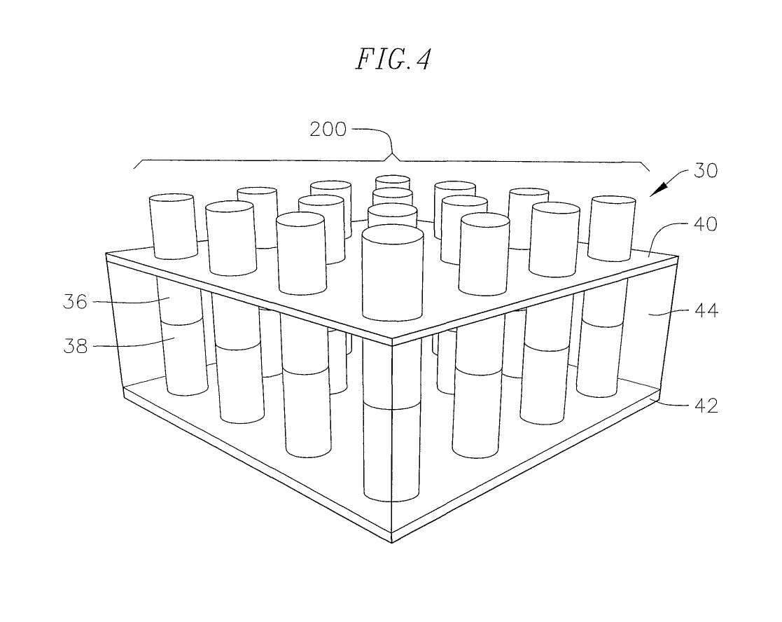

Further, as can be seen in FIG. 2A, light is transmitted through the coating (e.g., the portion of the coating 36 that partially or fully covers one end of the microwire 34) and into the microwire 34. Although a substantial portion of the incident light is transmitted through the coating 36, some portion of the incident light may also be transmitted into the microwire 34 without having passed through the coating 36 first, for example, by being transmitted into the microwire 34 by way of the portions of the microwire 34 that are not coated or covered by the coating 36. Additionally, some portion of the incident light may be absorbed by the coating 36, thereby reducing the amount of incident light transmitted into the microwire 34. This configuration with respect to the direction of propagation of incident light is referred to as a “front,” “as-grown,” or “through a-Si” configuration. Accordingly, FIG. 2A shows a microstructure 30 having a “radial-front” configuration. In addition, FIG. 3 shows a perspective cross-sectional view of the radial-front configuration, and FIG. 4 shows a perspective view of an array 200 of microstructures 30 arranged in the radial-front configuration.

Similarly to FIG. 2A, FIG. 2B shows a configuration in which the coating 36 (e.g., the emitter) is on (e.g., concentrically on) more than half of the elongated portion of the microwire 34. As such, the coating 36 at least partially covers the elongated portion of the microwire 34. Additionally, in this embodiment, the coating 36 may also partially or fully cover one end of the microwire 34. As with FIG. 2A, this embodiment is referred to as a “radial” configuration (i.e., a radial junction).

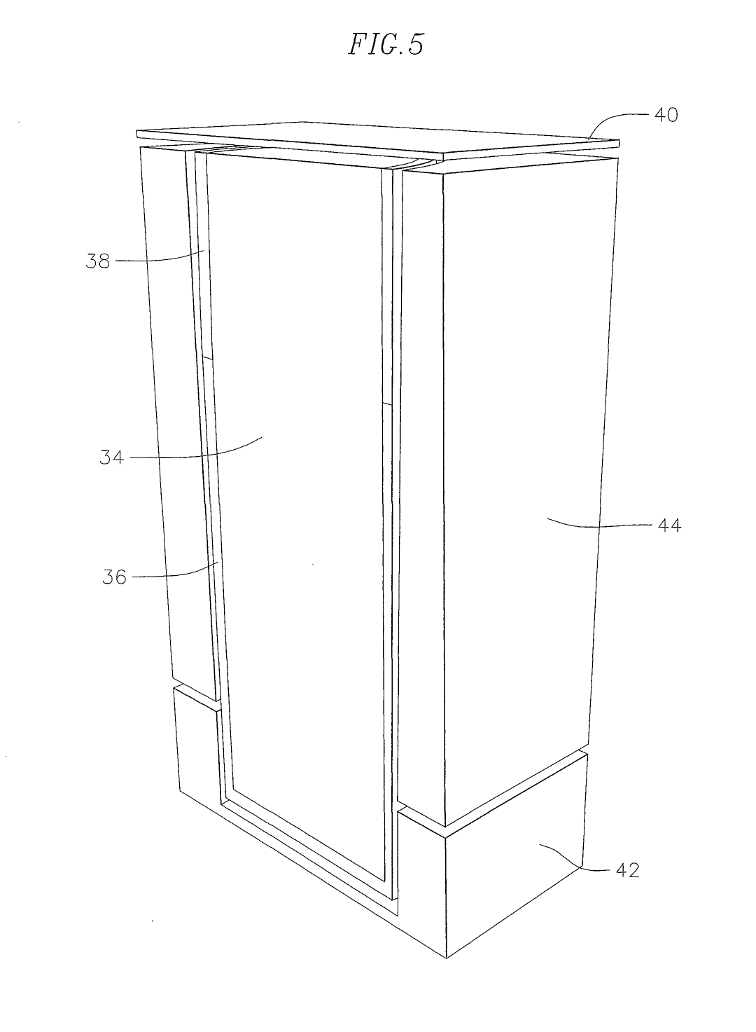

Unlike FIG. 2A, however, in the exemplary embodiment shown in FIG. 2B, light is transmitted into the microwire 34 without having passed through the coating 36 first. Although a substantial portion of the incident light is transmitted into the microwire 34 without having passed through the coating 36 first, some portion of the incident light may be transmitted into the microwire 34 after having passed through the coating 36 first. Additionally, some portion of the incident light may be absorbed by the coating 36, thereby reducing the amount of incident light transmitted into the microwire 34. This configuration with respect to the direction of propagation of incident light is referred to as a “back,” “inverted,” or “through” configuration. Accordingly, FIG. 2B shows a microstructure 30 having a “radial-back” configuration. In addition, FIG. 5 shows a perspective cross-sectional view of the radial-back configuration, and FIG. 4 shows a perspective view of an array 300 of microstructures 30 arranged in the radial-back configuration.

FIG. 2C shows a configuration in which the coating 36 is on (e.g., concentrically on) one end of the microwire 34. For example, in FIG. 2C, the coating partially or fully covers one end of the microwire 34. In this embodiment, the coating 36 may also cover some portion of the elongated portion of the microwire 34, however, in this embodiment the coating 36 is not on more than half of the elongated portion of the microwire 34. For example, in this embodiment, the coating 36 (e.g., the emitter) is on less than half of the elongated portion of the microwire 34. This embodiment is referred to as an “axial” configuration (i.e., an axial junction).

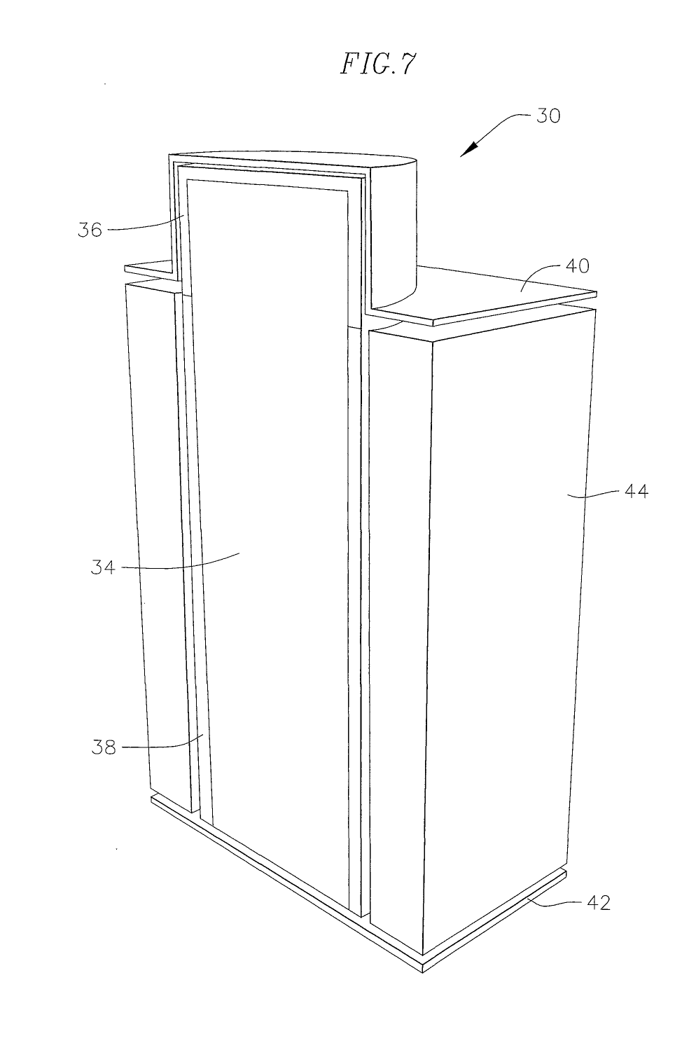

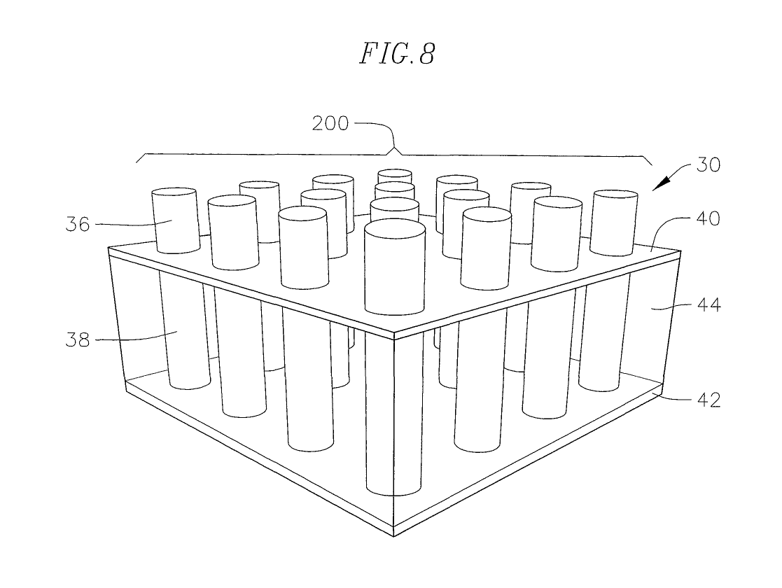

Further, as can be seen in FIG. 2C, light is transmitted through the coating 36 (e.g., the portion of the coating 36 that partially or fully covers one end of the microwire 34) and into the microwire 34. Although a substantial portion of the incident light is transmitted through the coating 36, some portion of the incident light may also be transmitted into the microwire 34 without having passed through the coating 36 first, for example, by being transmitted into the microwire 34 by way of the portions of the microwire 34 that are not coated or covered by the coating 36. Additionally, some portion of the incident light may be absorbed by the coating 36, thereby reducing the amount of incident light transmitted into the microwire 34. This configuration with respect to the direction of propagation of incident light is referred to as a “front,” “as-grown,” or “through a-Si” configuration. Accordingly, FIG. 2C shows a microstructure 30 having an “axial-front” configuration. In addition, FIG. 7 shows a perspective cross-sectional view of the axial-front configuration, and FIG. 8 shows a perspective view of an array 400 of microstructures 30 arranged in the axial-front configuration.

Similarly to FIG. 2C, FIG. 2D shows a configuration in which the coating 36 is on (e.g., concentrically on) one end of the microwire 34. For example, in FIG. 2D, the coating partially or fully covers one end of the microwire 34. In this embodiment, the coating 36 may also cover some portion of the elongated portion of the microwire 34, however, in this embodiment the coating 36 is not on more than half of the elongated portion of the microwire 34. For example, in this embodiment, the coating 36 (e.g., the emitter) is on less than half of the elongated portion of the microwire 34. This embodiment is referred to as an “axial” configuration (i.e., an axial junction).

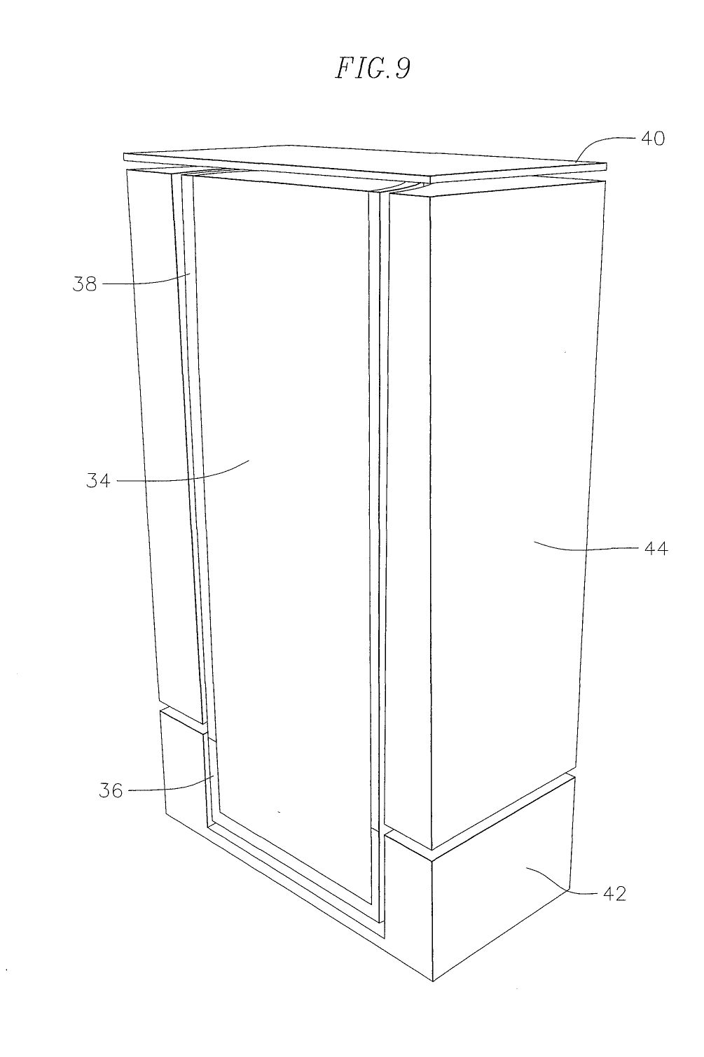

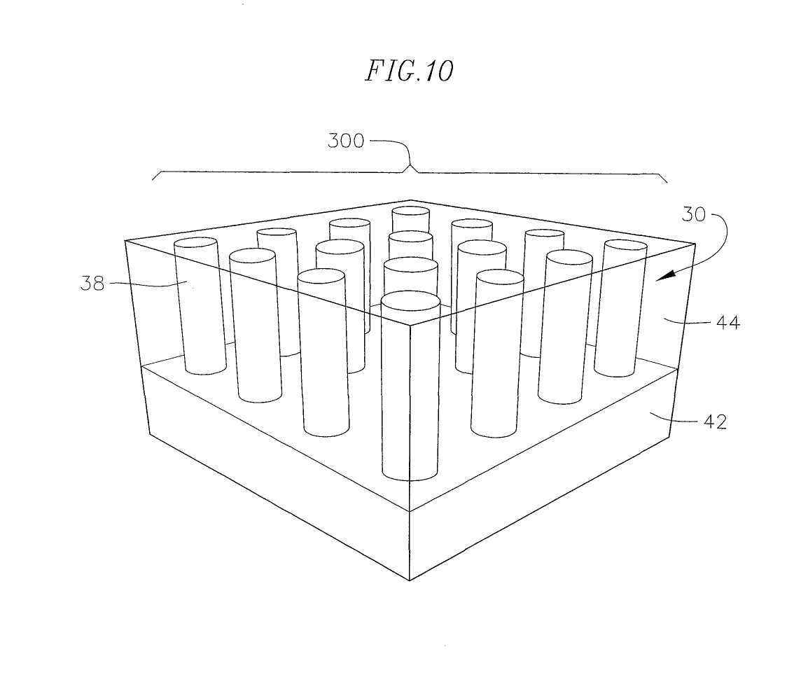

Unlike FIG. 2C, however, in the exemplary embodiment shown in FIG. 2D, light is transmitted into the microwire 34 without having passed through the coating 36 first. Although a substantial portion of the incident light is transmitted into the microwire 34 without having passed through the coating 36 first, some portion of the incident light may be transmitted into the microwire 34 after having passed through the coating 36 first. Additionally, some portion of the incident light may be absorbed by the coating 36, thereby reducing the amount of incident light transmitted into the microwire 34. This configuration with respect to the direction of propagation of incident light is referred to as a “back,” “inverted,” or “through” configuration. Accordingly, FIG. 2D shows a microstructure 30 having an “axial-back” configuration. In addition, FIG. 9 shows a perspective cross-sectional view of the axial-back configuration, and FIG. 10 shows a perspective view of an array 500 of microstructures 30 arranged in the axial-back configuration.

As can be seen in FIGS. 2A through 2D, the microstructures 30 may be configured to be substantially parallel to the direction of propagation of incident light. Consequently, in exemplary embodiments of the invention, light is absorbed along the length of the microwire 34. This configuration accommodates absorption lengths that are longer than those suitable for certain planar heterojunction devices (i.e., devices fabricated on wafers or contiguous planar semiconductor films). Additionally, in the radial configuration, a substantial portion of the minority charge carriers diffuse radially across the p-i-n junction (i.e., the heterojunction). That is, minority charge carriers will diffuse radially from the microwire 34 to the coating 36. Because the radial configuration also includes some amount of axially oriented coating, minority charge carriers may also diffuse axially across the p-i-n junction, however, in such an embodiment, a substantial portion of the minority charge carriers should diffuse radially. Microstructures 30 configured to radially diffuse minority charge carriers and configured to absorb light along the length of the microwire 34 are beneficial for microwires including low purity c-Si in which the absorption length is much larger than the minority charge carrier diffusion length. Microwires fabricated by the VLS method with silicon nitride passivation have attained minority carrier diffusion lengths reaching above 30 microns. With diffusion lengths this large, a radial junction may not be necessary, and a shorter junction may suffice to efficiently collect photogenerated carriers, while also reducing dark current as a result of the corresponding decrease in junction area.

Microstructures 30 that are configured to have light absorption along the length of the microwire 34, but which allow radial diffusion and collection of minority charge carriers may have a minority charge carrier diffusion length that is significantly shorter than the optical absorption length. When such a microstructure 30 includes c-Si in the microwire 34, the purity of the c-Si may be much lower than that used for planar heterojunction applications, because in the planar case, the minority charge carrier collection length must be at least on the order of the optical absorption length. Consequently, solar cells including microstructures 30 according to embodiments of the invention should be significantly less expensive to produce than analogous planar heterojunction solar cells, as the solar cells including microstructures 30 would include substantially less c-Si, which is a substantial component of the cost in producing the planar heterojunction cells.

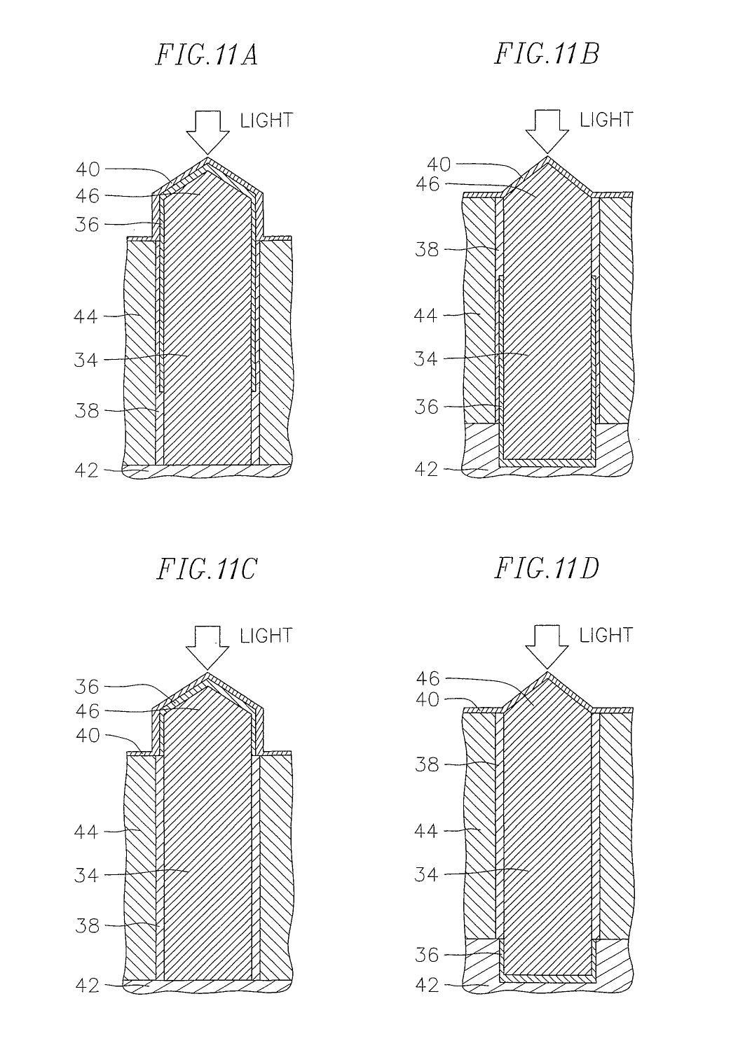

FIGS. 11A through 11D are similar to FIGS. 2A through 2D, except that in FIGS. 11A through 11D, each microstructure 30 includes a pyramidal or conical end 46. The pyramidal or conical end 46 may be formed of the same material as the microwire 34 (e.g., c-Si), or it may be formed of a different material (e.g., a transparent conductive oxide or anti-reflective coating). For example, the pyramidal or conical end 46 may be formed by introducing anti-reflective (AR) texturing on the light facing surface of the microwire 34, or it may be formed by introducing AR texturing on another component of the microstructure 30. The AR texturing (e.g., the pyramidal or conical end 46) may be formed by, for example, etching with an etching solution, such as KOH, or photochemical etching in HF.

Changing the shape of the end of the microstructure 30 from flat or cylindrical to pyramidal or conical reduces reflection losses. As light reaches the microstructure 30, a portion of the light may be reflected. When light reaches a flat or circular end of a microwire 34, the reflected portion of the light is reflected away from the microwire 34 and from the array generally. Consequently, this reflected portion of light will not substantially contribute to photogeneration in the array, unless the reflected light is again reflected back toward the array.

In contrast, when light reaches the pyramidal or conical ends 46, at least a portion of the reflected light is reflected toward another microstructure in the array. This provides opportunity for the other microstructures to at least partially capture this reflected light. Consequently, more light is captured by the microstructures as a result of the pyramidal or conical ends 46.

In certain embodiments, the microwires 34 each have a diameter that is greater than 1 μm. In other embodiments, the microwires 34 each have a diameter in a range of about 1 μm to about 10 μm. For example, the microwires 34 each may have a diameter in a range of about 1.5 μm to about 4 μm. As the diameter of the microwire 34 increases, the path length also increase, thereby increasing photogeneration and device efficiency.

In simulations of photovoltaic devices (described further below) carried out by the present inventors, the combination of pyramidal ends 46 and a microwire diameter of 3 μm resulted in photogeneration rates in excess of 34.5 mA/cm² in the c-Si microwire without appreciable absorption in the amorphous silicon coating, for the axial-back configuration, under standard illumination conditions. Without being limited by theory, the present inventors believe that the improvement is due to increased response in the near-infrared region. For example, the simulations revealed that the c-Si absorption at 1050 nm rises from 11% for 1.6 μm diameter microwires with flat ends to 29% for 3 μm diameter microwires with pyramidal ends. It is believed that this improvement is due to an increase of the path length of the light in the microwire 34 as a result of the increase of the diameter of the microwire, as well as reduced surface reflection due to the AR texturing.

Furthermore, in certain embodiments, the microwires 34 each have a length greater than 75 μm. In other embodiments, the microwires 34 each have a length in a range of about 25 μm to about 300 μm. For example, the microwires 34 each may have a length in a range of about 50 μm to about 100 μm.

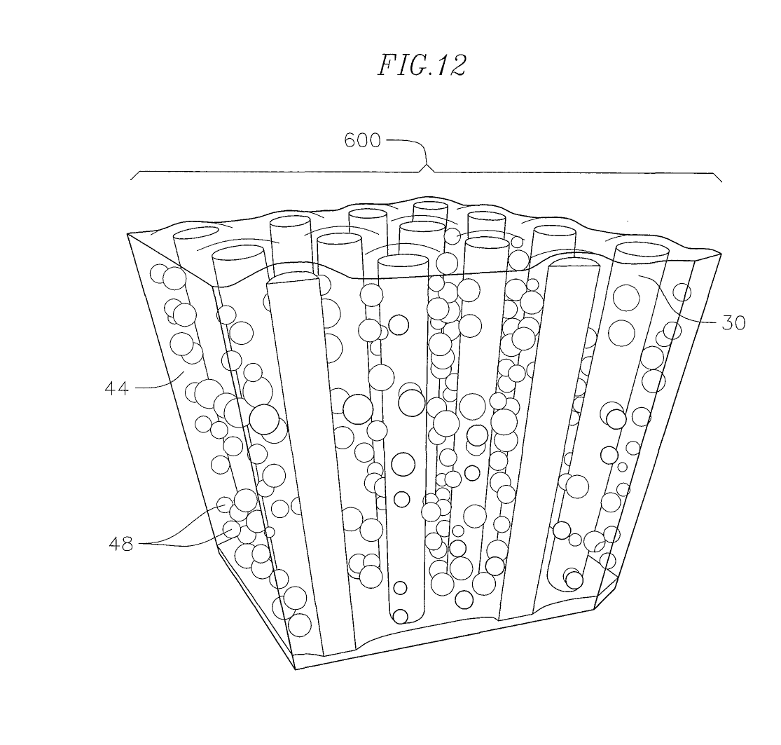

Additionally, certain embodiments of the invention may also include “light trapping elements,” such as, but not limited to, antireflective layers, light scattering particles, reflectors, tapered layers, and equivalents thereof. For example, certain embodiments of the invention include light-trapping elements such as those described in U.S. patent application Ser. No. 12/957,065, and Kelzenberg, M. D., Boettcher, S. W., Petykiewicz, Turner-Evans, D. B., Putnam, M. C., Warren, E. L., Spurgeon, J. M., Briggs, R. M., Lewis, N. S., and Atwater, H. A. (2010) Nature Materials 2365, the entire contents of each of which are herein incorporated by reference. In certain embodiments, the array may include alumina or titanium dioxide particles to scatter or trap light. For example, FIG. 12 is a perspective view showing an array 600 of microstructures 30, infill material 44, and scattering particles 48.

Furthermore, in embodiments of the invention the second electrical contact 42 may include a Ag or Al back-reflector layer to improve absorption. In other embodiments, long-wavelength absorption may be increased by switching the trapping mechanism from scattering to coupling of light into modes perpendicular to the direction of illumination (i.e., by creating a photonic crystal), using graded structures for optical impedance matching, and/or direct minimization of reflection. For example, the long-wavelength may be increased according to the description of Lin, C. and Povinelli, M. L. Optics Express, (2009) 17 (22), 19371, 10; and/or Zhu, J., Yu, Z., Burkhard, G. F., Hsu, C.-M., Connor, S. T., Xu, Y., Wang, Q., McGehee, M., Fan, S., and Cui, Y. Nano Letters (2009) 9(1):279-282, the entire contents of each of which are herein incorporated by reference.

As discussed above, because the microstructures 30 include microwires 34 and coatings 36 that have different light absorption characteristics, microstructures 30 according to embodiments of the invention interact with light anisotropically. That is, the microstructures 30 include at least two different materials having different light absorption properties, and the microstructures 30 should interact with light differently depending upon which material is illuminated first. As such, photogeneration in a solar cell including microstructures 30 will depend upon how the microstructures 30 are configured with respect to light illumination. For example, higher photogeneration efficiency is observed when a larger portion of incident light is absorbed in the microwire 34 as opposed to the coating 36. Conversely, lower photogeneration efficiency is observed when more of the incident light is absorbed by or transmitted through the coating 36 prior to being transmitted into the microwire 34. Accordingly, the present inventors have conducted an extensive investigation, by way of computational and theoretical modeling, to identify suitable exemplary embodiments of the microstructures 30 and solar cells including such microstructures. Prophetic examples according to this investigation are further described below.

Based on the simulations performed, the present inventors have determined that an axial configuration will reduce series resistance losses and yield better control over the thickness of the coating 36 (e.g., a-Si). Positioning the coating 36 between the microwire 34 and the second electrical contact, which may be transparent or reflective, will reduce series resistance. A thin intrinsic region may be deposited, if desired, and the remainder of the coating 36 may be n-type doped to improve conductivity and reduce trap state densities. In this case, the microwire 34 should be of p-type doping for an n⁺-i-p heterojunction. While it may not be necessary to prevent light absorption in the coating 36, the microstructures 30 may configured in the back-configuration to reduce light absorption in the coating 36. Additionally, in certain embodiments of the back configuration (e.g., the axial-back or radial-back configuration), the second electrical contact 42 may partially or fully envelope the coating 36.

Device-physics modeling using photogeneration profiles extracted from optical simulations yields V_{oc}'s of up to 643 mV. The simulated quantum yields of the devices with the highest V_{oc}'s are limited by absorption and recombination in the microwire 34, not by losses resulting from absorption in the coating 36. Optical absorption properties were calculated in 2-dimensional structures modeling arrays of c-Si microwires having radial or axial junctions to a-Si:H coatings using Finite-Difference Time-Domain (FDTD) full-field electromagnetic simulations. The simulated structures took into account the constraints imposed by deposition methods, such as PECVD, which tend to produce tapered coating thicknesses along the length of vertical microwires. Optical absorption of the microstructures was simulated using Lumerical FDTD software package. Simulations were performed using the radial-front, radial-back, axial-front, and axial-back configurations, as described above. The simulated c-Si microwires were 1.6 μm wide and 50 μm long. 5 μm long coatings of a-Si:H represented axial configurations, and a length of 35 μm represented the radial configurations. The thicknesses of the coatings were dependent on the length of the junction to model mass transport limitations that occur during PECVD deposition. For example, radial coatings had a thickness of 100 nm at the tip of the microwire and tapered to a thickness of 35 nm at the end of the junction. Axial coatings had a thickness of 20 nm at the tip of the microwire and a thickness of 10 at the end of the junction. The ARC 38 (e.g., SiNₓ) had a thickness of 130 nm at the tip of the microwire and tapered to a thickness of 35 nm at the end of the junction, to model the PECVD process. The first electrical contact 40 had a thickness of 70 nm.

In the simulations, having the second electrical contact 40 be reflective significantly increased optical absorption by doubling the path length through the device and mildly focusing the light on the microstructures 30 due to the tapering of the coating 36 and/or infill material 44. Addition of the ARC 38 further increased absorption, although its effect was somewhat offset by the simultaneous introduction of the first electrical contact 40 (i.e., ITO). ITO has a higher index of refraction than PDMS, which may be included in the infill material 44, and, therefore, increases the first pass reflection of light off of the array.

In the simulation results, the highest absorption was achieved for a radial configuration. While not being bound by theory, it is believed that this is a result of a-Si:H being a direct-gap semiconductor, and c-Si being an indirect bandgap semiconductor. Although a thin layer of can absorb a significant fraction of incident light (especially in the radial-front configuration), it does not serve to increase absorption in the c-Si because of its relatively high refractive index. However, even for a simple structure with no light-trapping elements, the use of an axial-back configuration can effectively reduce the amount of light absorption in the coating 36, without affecting absorption in the microwire 34. In the case of axial-back configuration, absorption in the coating 36 is calculated to be negligible (J_{ph,a-Si} 0.1 mA/cm²), as it is sandwiched between microwire 34 and the second electrical contact 40, which may be reflective and thereby shield the coating 36 from direct illumination. Spectral absorption in the axial-back configuration was calculated to be relatively constant at ˜80-82% for wavelengths of light below 800 nm, with a drop-off in absorption for wavelengths above 800 nm.

Simulations performed by the present inventors also showed that, in the radial-back configuration, increasing the thickness of the second electrical contact, and thereby also the depth to which the microwire are embedded within the second electrical contact, decreased absorption in the coating 36, as the coating 36 becomes increasingly enveloped by the second electrical contact, which in this instance was reflective (e.g., opaque). Increasing the thickness of the second electrical contact resulted in a corresponding decrease in the thickness of the infill material 44, as it was displaced by the second electrical contact. The simulations, however, indicated that photogeneration in the microwire 34 was unaffected by the gradual replacement of the infill material 44 (e.g., PDMS), ARC 38 and scattering particles 48, by the second electrical contact 40. According to these simulations, the infill material 44 can be compressed to a thickness of about 15 μm without a substantial loss of absorption in the microwire 34.

The array of microstructures according to embodiments of the invention may be prepared by any suitable method. For example, the array of microstructures 30 may be grown and processed (e.g., contacted) in place. Alternatively, the array may be etched from a wafer or film rather than grown or deposited, in which case, the substrate from which it was etched is hereafter also referred to as the growth substrate. The array may be removed from the growth substrate (e.g., the support 32). In certain embodiments, the array substantially retains its original array structure (with respect to the orientation of the microstructures 30 relative to one another) after removal from the growth substrate. Additionally, further processing (e.g., contacting) performed after removal from the growth substrate may not substantially alter the original array structure (with respect to the orientation of the microstructures 30 relative to one another). Uniform growth of microwires including c-Si is possible over areas comparable to that of commercial solar cells (i.e., over a six-inch wafer).

For example, the microwires may be grown via a vapor-liquid-solid (VLS) chemical vapor deposition (CVD) procedure. For example, the microwires can be grown according to the VLS procedure described in Kayes, B. M., Filler, M. A., Putnam, M. C., Kelzenberg, M. D., Lewis, N. S., and Atwater, H. A. (2007) Applied Physics Letters 91(10), 103110; Kelzenberg, M. D., Boettcher, S. W., Petykiewicz, J. A., Turner-Evans, D. B., Putnam, M. C., Warren, E. L., Spurgeon, J. M., Briggs, R. M., Lewis, N. S., and Atwater, H. A. (2010) Nature Materials 9, 238-244. For example, the microwires may be grown or fabricated by the methods, and have the resulting dimensions, described in U.S. patent application Ser. No. 12/176,057, the entire contents of which are herein incorporated by reference. The microwires also may be prepared using the templating technique described in U.S. patent application Ser. No. 12/176,099, the entire contents of which are herein incorporated by reference.

In certain embodiments of the invention, the microstructures may be 3-dimensionally patterned according to the methods described in U.S. patent application Ser. No. 12/956,0422; Putnam, M. C., Boettcher, S. W., Kelzenberg, M. D., Turner-Evans, D. B. Spurgeon, J. M., Warren, E. L., Briggs, R. M., Lewis, N. S., and Atwater, H. A. Energy & Environmental Science, 2010, 3, 1037-1041; and Kelzenberg, M. D., Turner-Evans, D. B., Putnam, M. C., Boettcher, S. W., Briggs, R. M., Baek, J. Y., Lewis, N. S., and Atwater, H. A. Energy & Environmental Science, 2011, 4, 866-871, the entire contents of each of which are herein incorporated by reference. For example, the above-referenced three-dimensional patterning techniques may be used to fabricate coatings 36 of the second semiconductor material along various portions of the microwires 34, thereby obtaining either “axial” or “radial” junction geometries as discussed above.

In certain embodiments, the microstructures are embedded in an infilling material (e.g., polymer) such as those described in U.S. patent application Ser. No. 12/176,065, the entire contents of which are herein incorporated by reference. Additionally, as described therein, the microstructures embedded in the infilling material (e.g., polymer) may be peeled off as a polymer-embedded film and inverted for “rear” illumination, such as the axial-back and radial-back configurations described above. Further, once a polymer-embedded film has been peeled off the growth substrate, the growth substrate may be re-used in the manner described in U.S. patent application Ser. No. 12/176,100, the entire contents of which are herein incorporated by reference.

According to a non-limiting exemplary embodiment, an n⁺ Si(111) substrate, previously covered with thermal oxide, may be patterned lithographically, and oxide may be removed via a photomasked HF etch. The VLS catalyst may be deposited onto the exposed regions of the Si substrate by thermal evaporation followed by liftoff of the mask. The substrate may be annealed, for example for a time period of 20 minutes and at a temperature of 1000° C. in hydrogen gas, and microwires may be grown by introducing 2% SiCl₄ in H₂ for 30 minutes. In certain embodiments, a gas is introduced during the growing of the array of microstructures and the gas composition is controlled to produce an axial or radial doping profile Any suitable starting material for forming a suitable silicon semiconductor may be used. For example, any suitable silane derivative, such as a chlorosilane may be used. The remaining catalyst may be removed by immersion in a suitable solution. For example, a Cu catalyst may be removed by immersion in aqueous solutions of HCl and H₂O₂; Au catalyst may be removed by immersion in an aqueous solution of FeCl₃, then KOH, and then HF. The microwires may be oxidized thermally to avoid future shunting from substrate to coating and prepare a clean and maximally defect-free surface for coating deposition.

The oxidized microwires may be immersed in PDMS, and the polymer may be shrunk under heat until a layer of it covers the base portion of the microwires. The exposed oxide on the upper portion of the microwires may then be etched with HF. The a-Si:H coating 36 may be deposited by plasma-enhanced hot wire chemical vapor deposition (PECVD). For example, the a-Si:H may be deposited as described in Schaper, M., Schmidt, J., Plagwitz, H., and Brendel, R. Progress in Photovoltaics: Research and Applications 13 (5), 381-386, and Wang, T., Iwaniczko, E., Page, M., Levi, D., Yan, Y., Branz, H., and Wang, Q. Thin Solid Films 501(1-2), 284-287 Proceedings of the Third International Conference on Hot-Wire CVD (Cat-CVD) Process, the entire contents of each of which are herein incorporated by reference. In certain embodiments, the deposition of the second semiconductor material includes a method selected from the group consisting of plasma-enhanced chemical vapor deposition (PECVD), hot-wire chemical vapor deposition (HWCVD), metalorganic chemical vapor deposition (MOCVD), atmospheric pressure chemical vapor deposition (APCVD), low pressure chemical vapor deposition (LPCVD), atomic layer deposition (ALD), evaporation, sputtering, and combinations thereof. For example, the a-Si:H coating may be deposited by plasma-enhanced chemical vapor deposition (PECVD) or hot-wire chemical vapor deposition (HWCVD) at temperatures in a range of about 180 to about 225° C., respectively. P-type doping can be produced by introducing, for example, B(CH₃) or B₂H₆, whereas n-type doping can be produced by introducing PH₃. Intrinsic layers are deposited in the absence of an extrinsic dopant precursor.

In certain embodiments, the thickness of the intrinsic buffer layer a-Si will be in a range of about 5 nm to about 10 nm.

TABLE 1

| | | J_{sc}, | | |
|---|---|---|---|---|
| Geometry Configuration | η, % | mA/cm² | V_{oc}, mV | FF, % |
| Radial junction, front-illuminated | 8.2 | 17.8 | 598 | 77.6 |
| Radial junction, back-illuminated | 10.1 | 21.1 | 609 | 78.9 |
| Axial junction, front-illuminated | 10.1 | 19.2 | 643 | 82.6 |
| Axial junction, back-illuminated | 7.8 | 14.9 | 636 | 82.8 |

### EXAMPLE 1

Hydrogenated amorphous silicon was grown on glass substrates using PECVD using the a-Si:H growth parameters shown in Table 2, using 5% SiH₄ in argon with 141 ppm trimethylboron (TMB) at 225° C., 500 mTorr and 3 W radio frequency (RF) power.

TABLE 2

| | | R, equation |
|---|---|---|
| SiH₄/TMB, sccm | H₂, sccm | (1) |
| 50 | 0 | 0 |
| 50 | 25 | 10 |
| 50 | 50 | 20 |

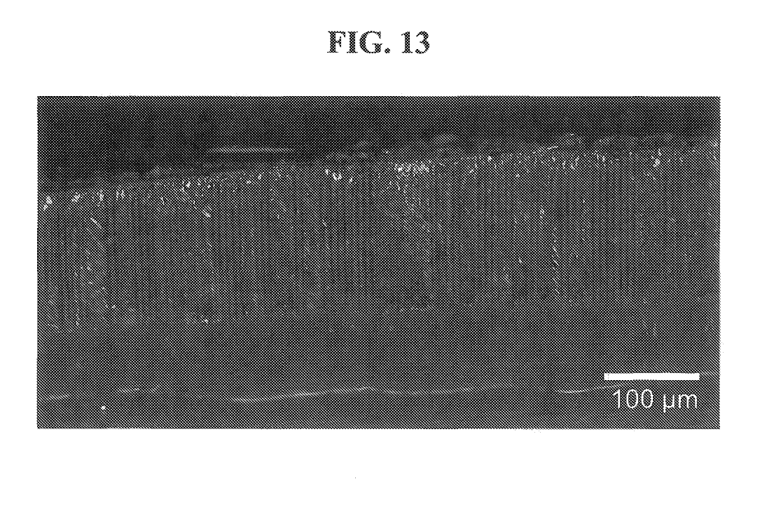

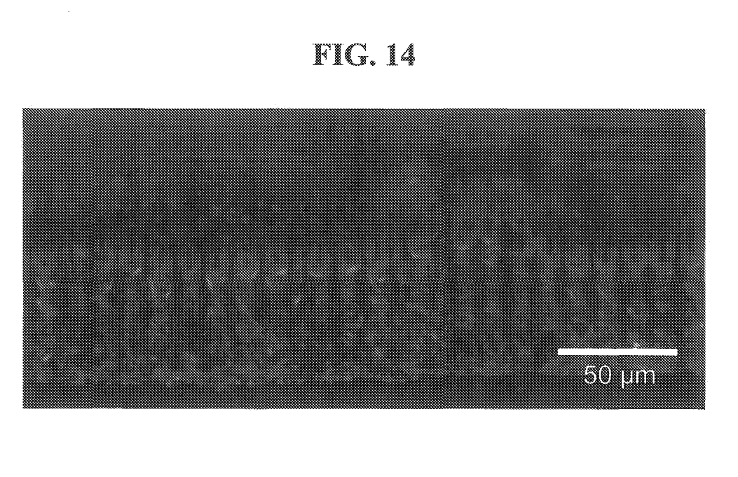

Optical micrographs of c-Si:a-Si microwire arrays fabricated for illumination through the c-Si microwires (i.e., front illumination) are shown in FIGS. 13 and 14. Specifically, FIG. 13 shows 128 μm-long microwires on Cu tape (shown at the bottom of the micrograph). FIG. 14 shows 70 μm-long microwires on Cu tape (shown at the top of the micrograph). Both FIGS. 13 and 14 show wicking of the Cu tape adhesive.

The optical properties of the samples were analyzed using ellipsometry (Sentech SE850) and Raman spectroscopy with an Ar ion laser (514 nm). The (Ψ,Δ) spectra obtained from ellipsometry were fitted to the Forouhi-Bloomer model to obtain the complex index of refraction. The charge carrier lifetime was measured using contactless photoconductivity decay from excitations with 10-ns pulses at 532 nm from a Nd:YAG laser operating at 10 Hz. Photoconductivity decay was fit to a single exponential of the form y(t)=Ae^{-1/τ}+y₀. Contacts for electrical measurements were fabricated (Table 3) using either shadow masks or photolithographical patterning immediately after a dip in concentrated buffered HF for over 1 minute. Conductivity of the a-Si:H samples was measured using a van der Pauw setup to eliminate contact resistance from the measurement. Hall measurements were conducted on the same setup, with absolute magnitudes of Hall currents around 20 nA, limited by low sample thickness and high resistivity. Growing thicker samples resulted in formation of microcrystalline layers. Secondary-Ion Mass Spectroscopy (SIMS) analysis was ordered from Evans Analytical. The sputtering beam was Cs⁺.

TABLE 3

| | | RF power, | | | |
|---|---|---|---|---|---|
| | | W/DC | | Pressure, | Rate, |
| Material | Technique | Voltage V | T, ° C. | mTorr | Å/s |
| ITO | RF | 150/106 | 200 | 3 | 0.6 |
| | Sputtering | | | | |
| AZO | RF | 110/79 | 250 | 3 | 1.1 |
| | Sputtering | | | | |
| Al/Ag | Evaporation | — | Room | ~7 | ~10 |

While the array architecture described herein may suffer a loss in open circuit voltage (V_{oc}) due to its high aspect ratio (γ in equation 1, shown above), it may offset this loss by way of enhanced carrier collection due to the radial junction structure, or due to any of the other above-described features. The ratio of electron and hole currents across the junction is given by equation 2 (shown above), where ΔE_{g} is the difference in bandgaps across the junction, and the rest of the parameters are characteristic of the specific microwire 34 (e.g., the absorber) and coating 36. Hence, the substitution of a-Si, a wider bandgap material than c-Si, should enhance the charge separation efficiency exponentially by preventing minority carrier diffusion across the junction due to the built-in field barrier to recombination. Low recombination at the interface allows for near-record V_{oc} and efficiency. Use of a wide-bandgap coating 36 also decreases light absorption by the coating 36, as a smaller part of the solar spectrum bears enough energy to excite the coating 36. Thus, use of a-Si instead of c-Si should also enhance the optical absorption properties of the device and possibly increase short-circuit current output of the device. Thus, a combination of the two technologies, the heterojunction and the array architecture, should yield an improvement in photovoltaic device efficiency.

While the present invention has been described in connection with certain exemplary embodiments, it is to be understood that the invention is not limited to the disclosed embodiments, but, on the contrary, is intended to cover various modifications and equivalent arrangements included within the spirit and scope of the appended claims, and equivalents thereof.

What is claimed is:

1. A heterojunction semiconductor device comprising:
an array of microstructures, each microstructure comprising a microwire of a first semiconductor material and a coating of a second semiconductor material forming a heterojunction with the microwire;
a first electrical contact and a second electrical contact, one of which is connected to the microwire and the other of which is connected to the coating.

2. The heterojunction semiconductor device of claim 1, wherein the first semiconductor material comprises a material selected from the group consisting of Si, Ge, SiGe, GaAs, CdTe, CdSe, GaN, GaP, GaAsP, GaInP, AlInP, InGaN, and combinations thereof.

3. The heterojunction semiconductor device of claim 1, wherein the second semiconductor material comprises a material selected from the group consisting of Si, Ge, SiGe, GaAs, CdTe, CdSe, GaN, GaP, GaAsP, GaInP, AlInP, InGaN, and combinations thereof.

4. The heterojunction semiconductor device of claim 1, wherein the microwire is configured to be substantially parallel to the direction of propagation of incident light.

5. The heterojunction semiconductor device of claim 1, wherein the heterojunction is a p-i-n or n-i-p heterojunction.

6. The heterojunction semiconductor device of claim 1, wherein the coating concentrically surrounds a portion of the microwire.

7. The heterojunction semiconductor device of claim 6, wherein the coating concentrically surrounds less than half of the elongated portion of the microwire.

8. The heterojunction semiconductor device of claim 6, wherein the coating concentrically surrounds more than half of the elongated portion of the microwire.

9. The heterojunction semiconductor device of claim 1, wherein the coating on each microwire is discontinuous with the coating on adjacent microwires.

10. The heterojunction semiconductor device of claim 1, wherein the first electrical contact or the second electrical contact comprises a semiconductor that forms a non-rectifying heterojunction to the microwire.

11. The heterojunction semiconductor device of claim 1, wherein the microwire has a diameter in a range of about 1 μm to about 10 μm.

12. The heterojunction semiconductor device of claim 11, wherein the microwire has a diameter in a range of about 1.5 μm to about 4 μm.

13. The heterojunction semiconductor device of claim 1, wherein the microwire has a length of greater than 50 μm.

14. The heterojunction semiconductor device of claim 1, wherein at least a portion of the coating has a thickness in a range of about 5 nm to about 10 nm.

15. The heterojunction semiconductor device of claim 1, wherein one end of the microstructure has a pyramidal or conical shape.

16. The heterojunction semiconductor device of claim 1, wherein the second semiconductor material comprises a dopant in a range of about 1 to about 10 weight percent based on the total weight of the second semiconductor material.

17. The heterojunction semiconductor device of claim 1, wherein the microstructures are partially or fully embedded in an infill material.

18. The heterojunction semiconductor device of claim 17, wherein the infill material comprises a polymer.

19. The heterojunction semiconductor device of claim 1, wherein the microstructure further comprises an anti-reflective coating.

20. A method of preparing an array of microstructures for a heterojunction semiconductor device, the method comprising:
growing an array of microwires on a substrate, the microwires comprising a first semiconductor material; and
depositing a second semiconductor material on a portion of the microwires to form a heterojunction.

21. The method of claim 20, wherein growing the array of microwires comprises vapor-liquid-solid (VLS) chemical vapor deposition (CVD).

22. The method of claim 21, wherein the substrate comprises a VLS catalyst.

23. The method of claim 21, wherein the VLS catalyst is a copper or nickel catalyst.

24. The method of claim 21, wherein the VLS deposition is carried out with a gas flow comprising hydrogen and a chlorosilane.

25. The method of claim 19, wherein a gas is introduced during the growing of the array of microstructures and the gas composition is controlled to produce an axial or radial doping profile.

26. The method of claim 20, wherein the array of microwires is removed from the substrate on which it was grown.

27. The method of claim 22, wherein the deposition of the second semiconductor material comprises a method selected from the group consisting of plasma-enhanced chemical vapor deposition (PECVD), hot-wire chemical vapor deposition (HWCVD), metalorganic chemical vapor deposition (MOCVD), atmospheric pressure chemical vapor deposition (APCVD), low pressure chemical vapor deposition (LPCVD), atomic layer deposition (ALD), evaporation, sputtering, and combinations thereof.

28. The method of claim 20, wherein the second semiconductor material is deposited conformally over the array of microstructures and selectively removed from a portion of the array of microstructures using lift-off, ablation, or an etch.
